(19) United States
(12) Patent Application Publication
(10) Pub. No.: US 2021/0302548 A1
(43) Pub. Date: Sep. 30, 2021

(54) METHOD AND APPARATUS FOR DETERMINING MEASUREMENT INFORMATION AND LIDAR DEVICE

(71) Applicant: Fraunhofer-Gesellschaft zur Förderung der angewandten Forschung e.V., München (DE)

(72) Inventors: Gongbo CHEN, Duisburg (DE); Pierre GEMBACZKA, Duisburg (DE); Burkhard HEIDEMANN, Duisburg (DE)

(21) Appl. No.: 17/249,964

(22) Filed: Mar. 19, 2021

(30) Foreign Application Priority Data
Mar. 24, 2020 (DE) 102020203796.5

(51) Int. Cl. G01S 7/4863; H01L 31/107; G01S 17/89

(52) U.S. Cl. CPC G01S 7/4863; G01S 17/89; H01L 31/107

(57) ABSTRACT

A method for determining measurement information based on a multitude of measurement values from a measurement value range includes: obtaining a frequency distribution of a plurality of measurement values; dividing the frequency distribution into several regions, wherein one of the regions each represents an interval of the measurement value range and includes one or several classes of the frequency distribution; selecting one class each of a respective region as a selected class of the respective region based on a selection rule, wherein one region feature each is allocated to the regions based on the selection rule, determining a probability value for one of the selected classes based on the region features, wherein the probability value represents an estimation for the probability with which the selected class represents a value of a useful signal, wherein determining the probability value is based on methods of machine learning.

### CROSS-REFERENCE TO RELATED APPLICATIONS

This application claims priority from German Patent Application No. 102020203796.5, which was filed on Mar. 24, 2020, and is incorporated herein in its entirety by reference.

Embodiments of the invention relate to the method and an apparatus for determining measurement information based on a plurality of measurement values of a measurement value range. Further embodiments relate to a light detection and ranging, LiDAR device. Some embodiments relate to a method for improving the reliability of LiDAR measurements by using machine learning and block-correlated analysis. Some embodiments relate to processing TCSPC histograms in a digital process stage of LiDAR systems.

### BACKGROUND OF THE INVENTION

When measuring a sought-for signal or useful signal, it is frequently difficult to distinguish whether the measurement value is based on the sought-for signal or whether the measurement value results from a background signal. For example, a measurement device for measuring the sought-for signal may be influenced or triggered by an interference signal of the same type as the sought-for signal, such that a measurement value generated by the measurement device results from the interference signal. Further, the background signal can be based, for example, on a noise of the measurement device. In particular, for very sensitive measurement devices or in cases where the sought-for signal is very weak, such that a signal to noise ratio is particularly small, it can thus be difficult to derive sought-for information from the measurement values.

One example of a particularly sensitive detector is a single-photon avalanche photodiode (SPAD) that is able to detect the energy of a single photon. A field of usage of the SPAD is depth mapping in LiDAR systems. The distance is determined by the time period between the emitted light pulse and the received echo on the SPAD. Based on this characteristic, the SPAD provides an exact mapping or image with high photon efficiency. While the SPAD benefits from its high sensitivity, the same results in significant erroneous detections due to ambient light, which decreases the reliability of the individual measurement and limits the resistance against ambient light. Time-correlated single photon counting, TCSPC, is an option of dealing with erroneous detections. Here, for example, a plurality of measurement values of the time period is determined per block or per image and collected in a histogram as frequency distribution. In advanced driver assistance systems (ADAS), depth information has to be available reliably and at the same time in real time under varying ambient light conditions. Thus, the random factor caused by the high block rate or image rate, i.e., a limited number of measurements per block and the extension of the current light situation, have to be considered as well.

Generally, digital processing used in LiDAR system runs a digital filter through the TCSPC histogram and detects the global maximum as absolute prediction, for example for the most probable value for the time of a detection or a distance travelled of the sought-for light pulse (with strong ambient light, estimation and removal of noise may be involved). For increasing prediction reliability, large effort has been invested in different processing stages of the LiDAR systems:

A basic approach is the usage of optical band-pass filters. This approach removes the largest part of the ambient light. However, selecting a narrow filter bandwidth range is difficult as the influence of production and temperature-induced variations is hard to estimate.

A second approach is the usage of a scanning LiDAR illuminating one point or one line of a scene each. This approach increases the optical power intensity at the expense of the field of view. This approach simplifies distinguishing the light pulse from the ambient light but results in asynchronous detection and reduction of the image rate of the scene.

A common approach for suppressing ambient light is coincidence detection. This approach includes several detectors in one pixel. These detectors operate in parallel. When two or more detectors are triggered in a defined time interval, a coincidence event will be generated. This approach prevents saturation of the SPAD by the strong ambient light. As the emitted light pulse is limited due to eye security and emitter technology, a suitable coincidence level that depends strongly on the ambient light intensity, the intensity of the received target light pulse, the target reflection and the target distance is to be carefully selected. Unfortunately, these factors are different. Thus, usually, this approach works reliably in one or several specific scenarios.

Another approach is time gating. The method uses fast electrical shutters to control the sensitivity of the sensor for photons by limiting the time interval in which the detectors are activated for photon detection. Normally, this approach involves knowing the approximate location of the object.

A further approach introduces spatial analysis with different algorithms such as deep learning via the point cloud data. By using the potential relation between different measurement points, this approach can also improve noise resistance up to a specific degree. However, reliable analysis involves a certain quality of the point cloud data, which is not ensured by front end processing.

Embodiments of the present disclosure can be used, for example, in the context of TCSPC or LiDAR and can use the above-described approaches.

### SUMMARY

According to an embodiment, a method for determining measurement information based on a multitude of measurement values from a measurement value range may have the steps of: obtaining a frequency distribution of a plurality of measurement values, wherein the measurement values of the frequency distribution are each allocated to one class of a plurality of classes of the frequency distribution, and wherein a frequency value of a class describes a number of measurement values allocated to the class, dividing the frequency distribution into several regions, wherein one of the regions each represents an interval of the measurement value range and includes one or several classes of the frequency distribution, selecting one class each of a respective region as a selected class of the respective region based on a selection rule, wherein one region feature each is allocated to the regions based on the selection rule, determining a probability value for one of the selected classes based on the region features, wherein the probability value represents an estimation for the probability with which the selected class represents a value of a useful signal, wherein determining the probability value is based on methods of machine learning.

Another embodiment may have an apparatus for determining measurement information based on a multitude of measurement values of a measurement value range, wherein the apparatus is configured to obtain a frequency distribution of a plurality of measurement values, wherein the measurement values of the frequency distribution are each allocated to a class of a plurality of classes of the frequency distribution and wherein a frequency value of a class describes a number of measurement values allocated to the class, divide the frequency distribution into several regions, wherein one of the regions each represents an interval of the measurement value range and includes one or several classes of the frequency distribution, select one of the classes each of a respective region as a selected class of the respective region based on a selection rule, wherein one region feature each is allocated to the regions based on a selection rule and determine a probability value for one of the selected classes based on the region features, wherein the probability value represents an estimation for the probability with which the selected class represents a value of a useful signal, wherein determining the probability value is based on a statistical model.

According to another embodiment, a LiDAR device may have the inventive apparatus and further: a light source configured to emit a light pulse and to provide a first signal in connection with emitting the light pulse, a detector configured to detect a photon and to provide a second signal as a result of detecting a photon, a correlator configured to determine, based on the first signal and the second signal, a time period between emitting the light pulse and detecting the photon and to provide the time period as a measurement value of the multitude of measurement values, wherein the measurement value represents a useful signal value when the photon is based on an echo of the light pulse, wherein the useful signal is based on one or several useful signal values and wherein the measurement information includes a position of the selected class of the frequency distribution with the highest probability value.

Another embodiment may have a non-transitory digital storage medium having a computer program stored thereon to perform the inventive method for determining measurement information based on a multitude of measurement values from a measurement value range when said computer program is run by a computer.

Embodiments of the present disclosure relate to a method for determining measurement information based on a multitude of measurement values from a measurement value range. The method includes obtaining a frequency distribution of a plurality of measurement values (the multitude of measurement values), wherein the measurement values of the frequency distribution are each allocated to one class of a plurality of classes of the frequency distribution, and wherein a frequency value of a class of the plurality of classes describes a number of measurement values allocated to the class (e.g., absolute or relative with respect to a total number of the plurality of measurement values of the frequency distribution). For example, one of the classes of the frequency distribution represents an interval of the measurement value to represent a position of the class in the measurement value range, i.e., for example, a position of a class represents the interval of the measurement value range represented by the class. Thus, a width of the interval can indicate an accuracy of the position of a class. The classes represent, for example, adjacent intervals of the measurement value range. Further, the method includes dividing the frequency distribution into several regions, for example, adjacent regions, wherein one of the regions each represents an interval of the measurement value range and includes one or several classes of the frequency distribution. Further, the method includes selecting one class each of a respective region (the regions) as a selected class of the respective region based on a selection rule, wherein one region feature each is allocated to the regions based on the selection rule. For example, the selection rule starts implies selecting the class having the highest or lowest frequency value of a region as the selected class of the region and to allocate the frequency value as region feature to the selected class. In further examples, the selected class and the region feature are determined based on the classes of a respective region by means of a function. The method includes determining a probability value (or certainty value) for one of the selected classes based on the region features, wherein the probability value represents an estimation for the probability with which the selected class represents a value of the useful signal, wherein determining the probability value is based on methods of machine learning (MML), e.g., an artificial neural network (ANN). For example, one probability value each can be determined for one or several or all of the selected classes. For example, the useful signal is based on part of the measurement values, such that the value of the useful signal is represented, for example, by the measurement values that are based on the useful signal.

Examples of the present disclosure are based on the idea that the measurement information can be determined in a particularly reliable manner based on the multitude of measurement values by using MML, i.e., for example, measurement accuracy can be increased, such that the determined measurement information represents the useful signal with a particularly high probability. This is obtained by the fact that the MML can access empirical values for determining the probability value, which have been trained, for example, by means of training data sets. Additionally, by using MML, a high robustness of determining the measurement information can be obtained. For example, by using MML, the measurement information can also be determined reliably when a total number of measurement values of the frequency distribution is low or an intensity of the useful signal is low compared to a background signal on which part of the multitude of measurement values can be based. By dividing the frequency distribution in regions to which one region feature each is associated, determining the probability values by using MML can be performed with particularly little computing effort and entail little memory space, e.g., since a number of regions can be smaller than a number of classes of the frequency distribution and hence a lower amount of data is to be processed by MML. Also, a model underlying the MML needs little memory space, as the method allows that the MML are only based on the region features of a plurality of frequency distributions and, for example, not on the plurality of measurement values of the frequency distributions. Further, selecting the selected class for one region and allocating the region feature to the region based on the selection rule allows allocating a probability value determined based on the region features to a selected class. Thereby, it can be achieved that an accuracy or resolution of the measurement information, for example a value of the useful signal to be determined, is based on an accuracy or resolution of a selected class, even if a classification of the MML is more inaccurate as the resolution of the classes of the frequency distribution. Thus, the measurement information can be determined more accurately than allowed by a resolution of the classification of the MML. Thus, determining the probability value based on the region features of the regions obtained by the division, to which one selected class each is allocated, allows determining the measurement information both with little computing effort and in an accurate manner.

According to an embodiment, the frequency distribution is part of a series of frequency distributions of a respective plurality of measurement values (the multitude of measurement values), wherein the method further includes comparing the selected classes to the selected classes of a previous frequency distribution of the series of frequency distributions (wherein the selected classes of the previous frequency distribution are selected based on the selection rule from respective regions of the previous frequency distribution) to adapt or maintain one or several of the region features depending on the comparison, and providing the region features for determining the probability value. The region features used for determining the probability value can be identical to the region features allocated to the regions based on the selection rule, or one, or several or all of the region features may have been adapted depending on the comparison. In examples, the selected classes of the frequency distribution can also be compared to the selected classes of several previous frequency distributions of the series of frequency distributions.

By the comparison, the previous frequency distribution can be used as previous knowledge for judging the probability with which the selected class represents the useful signal. For example, the comparison can be based on the knowledge or an estimation of a change of the useful signal between a generation of the previous frequency distribution and the frequency distribution. Based on an adaptation of a region feature based on the comparison, it can be obtained that the previous knowledge influences the probability value for the selected class accordingly. Thus, using previous knowledge from one or several previous frequency distributions for possible adaptation of the region features that serve as input data for determining the probability value can increase the accuracy or reliability of determining the probability values. In comparison to the usage of a previous frequency distribution for the comparison, by using several previous frequency distributions for the comparison, measurement uncertainty, e.g., based on statistical changes of a background signal, can be reduced. Further, additional information can be obtained, for example based on a temporal change of the useful signal. The additional information can be provided as part of the measurement information or can also be used to increase the reliability of determining the probability value by means of MML further.

According to an embodiment, comparing the selected classes to the selected classes of the previous frequency distribution of the series of frequency distributions includes comparing a position of one of the selected classes of the frequency distribution to the positions of one or several of the selected classes of the previous frequency distribution.

For example, comparing can be based on checking where the position of the selected class is located in relation to a position that is expected based on the position of the previous selected class, and adapting or maintaining the region feature depending thereon. For example, a type or strength of a possible adaptation can also be based on the comparison. Thus, based on a comparison, a measure for correlation or coincidence between the selected classes and the frequency distribution and the previous frequency distribution can be determined, which can be used as a measure for possible adaption of the region feature. Thus, the region feature can be sensitively adapted, for example, to a relative position of the selected class in relation to the selected class of the previous frequency distribution, whereby the adaption can be performed such that determining the probability value can take place in a particularly reliable manner.

According to an embodiment, comparing the selected classes to the selected classes of a previous frequency distribution of the series of frequency distribution includes selectively adapting the region feature of the region of a selected class (i.e., the region to which the selected class belongs) by considering a previous selected class, if the previous selected class is within a correlation interval, wherein the previous selected class is one of the selected classes of the previous frequency distribution.

For example, the region feature is adapted if the previous selected class is in the correlation interval and not adapted if the previous selected class is not in the correlation interval. A check whether the previous selected class is in the correlation interval can be performed with little computing effort and can at the same time be a reliable indicator for the probability value of the selected class.

According to an embodiment, comparing the selected classes to the selected classes of a previous frequency distribution of the series of frequency distributions includes determining a comparison position based on positions of one or several of the selected classes of several previous frequency distributions of the series of frequency distributions and selectively adapting the region feature of the region of one of the selected classes of the frequency distribution by considering the selected classes used for determining the comparison position if the comparison position is within a correlation interval.

By using several previous frequency distributions, the extent of previous knowledge can be increased and hence the reliability for correctness of an adaption of a region coefficient can be increased. For example, reliability of the comparison position, which can be considered for comparison, can be determined based on the positons of one or several of the selected classes of several previous frequency distributions. Thus, statistical uncertainties can be compensated.

According to an embodiment, adapting one of the region features is based on an adaptation coefficient, wherein the adaption coefficient is based on the probability value and/or the frequency value and/or a position of one or several selected classes of the previous frequency distribution.

The adaption coefficient represents, for example, a measure for adapting the region feature. Thus, the measure of adapting the region feature can be adapted according to the probability value and/or the frequency value and/or a position of one or several selected classes of the previous frequency distribution, whereby an adaptation reliability can be increased. For example, a high probability value or a high frequency value of a previous selected class can indicate that the previous selected class represents the value of the useful signal in the previous frequency distribution with high probability, such that in combination with an expected change a reliable prediction can be made for the probability value of a selected class of the frequency distribution and the region feature can be adapted accordingly. Considering the position of a selected class of the previous frequency distribution allows weighing a consideration of the selected class of the previous frequency distribution for the adaption coefficient according to a relative position of the selected class of the previous frequency distribution in relation to a position of a selected class of the frequency distribution and hence increasing the reliability of adapting the region feature.

According to an embodiment, adapting the region feature is based on an adaptation coefficient, wherein the adaption coefficient and/or the correlation interval is based on the probability value and/or the frequency value and/or a position of the considered previous selected class. In addition to the advantages described with respect to the adaption coefficient, considering the probability value and/or the frequency value and/or the positon of a previous selected class for the correlation interval allows considering the previous selected classes based on these parameters, which provides an option of little computing effort for adapting a measure for adapting the region feature based on these parameters.

According to an embodiment, comparing the selected classes to the selected classes of a previous frequency distribution of the series of frequency distributions includes determining a comparison positon based on positons of one or several of the selected classes of several previous frequency distributions of the series of frequency distributions and determining the adaption coefficient based on the probability values and/or the frequency values and/or the positions of the selected classes used for determining the comparison position.

According to an embodiment, adapting the region feature is based on an adaption coefficient, wherein the adaption coefficient and/or the correlation interval is based on the probability value and/or the frequency value and/or a position of the selected classes used for determining the comparison position.

According to an embodiment, the method further includes providing the adaption coefficient as part of the measurement information. For example, a value of the adaption coefficient may be an indicator for a change or a rate of change of the value of the useful signal, whereby the information content of the measurement information can be extended.

According to an embodiment, a position of the correlation interval in the measurement value range is based on a position of the selected class in the measurement value range and a width of the correlation interval is based on an expected change of the value of the useful signal. The expected change represents additional information by the consideration of which the effect of comparing the frequency distribution to the previous frequency distribution can be improved.

According to an embodiment, a position of the correlation interval in the measurement value range is based on a position of the selected class in the measurement value range and on an expected change of the value of the useful signal, and further, a width of the correlation interval is based on an expected change of the expected change of the value of the useful signal. By additionally using information on a change of the expected change, the effect of comparing the frequency distribution to the previous frequency distribution can be improved further.

Acceding to an embodiment, the method further includes determining the correlation interval and/or the adaption coefficient by using an artificial neural network (wherein the artificial neural network can be part of an artificial neural network for determining the probability value or a separate network).

Determining the correlation interval and/or the adaptation coefficient can take place, for example, based on a correlation interval and/or an adaptation coefficient of a previous frequency distribution or based on the region features of the frequency distribution. Thereby, for determining the correlation interval and/or the adaptation coefficient, it is possible to revert to trained empirical values, and hence these parameters can be selected such that a reliability for determining the probability value is increased.

According to an embodiment, the method further comprises determining, from the selected classes, the one with the highest probability value as a useful signal class and providing a position in the measurement value range represented by the useful signal class as part of the measurement information. By this selection of the useful signal class, a probability that the useful signal class represents the value of the useful signal is increased or maximized. Thus, the method allows providing, from the plurality of measurement values, a probable value of the useful signal as part of the measurement information.

According to an embodiment, the method further includes providing the probability value of the useful signal class as part of the measurement information. Based on this information, for example, a reliability whether the useful signal class represents the value of the useful signal can be judged.

According to an embodiment, selecting the selected classes includes selecting that class of one of the regions as selected class of the region that has the highest frequency value and wherein the region feature allocated to that region is based on the frequency value of the selected class of the region. Selecting according to the highest frequency value represents an implementation of the selection rule with little computing effort and can still provide a high probability that the selected class of the region is that class of the region comprising the highest probability to represent the useful signal. Thus, the probability that one of the selected classes of the frequency distribution represents the useful signal is increased.

According to an embodiment, the regions are equidistant and adjacent. By an adjacent selection, the frequency distribution can be mapped continuously without redundancies and equidistant regions can be easily determined, whereby the method can be implemented in a manner needing little computing effort.

According to an embodiment, a measurement value of the multitude of measurement values represents a time period between emitting a light pulse and detecting a photon (or the first detection of a photon after emitting the light pulse), wherein the measurement value either represents a useful signal value when the photon is based on the light pulse (e.g., based on an echo or reflection of the light pulse) or represents a background signal value (e.g., when the measurement value is based on a detector noise or detection of ambient light), and wherein the useful signal is based on one or several useful signal values. For example, a class of the frequency distribution can include both useful signal values as well as background signal values. By the type of determining the measurement information, the measurement information can also be determined in a very reliable and exact manner when a number of useful signal values is very small compared to a number of background signal values. This enables determining the measurement information in a reliable manner, even with strong ambient light and/or low intensity of the light pulse.

According to an embodiment, dividing the frequency distribution into the several regions includes selecting a width of one of the regions such that that class of the region into which a measurement value falling into that region falls with the highest probability represents a class of the useful signal if the useful signal falls into the region. Here, the probability distribution for the classes can be based, for example, on average or expected rates of the useful signal and a background signal, wherein optionally also a signal variation region within which the rates of the useful signal and the background signal can vary may be considered. In combination with the selection of that class of a region as the selected class of the region having the highest probability value, this type of dividing the frequency distribution ensures that the selected class of a region having high probability is that class of the region that has the highest probability of representing the useful signal. Assuming this criterion, this way of dividing ensures at the same time that the frequency distribution is divided into as few regions as possible, whereby computing power and storage capacity can be saved.

According to the embodiment, the methods of machine learning include an artificial neural network and the method includes training the artificial neural network based on the region features allocated to the regions of the frequency distribution. For example, training data sets for which the value of the useful signal is known can be used for training. By training, information on the region features can be used as additional empirical value for determining a probability value of a successive frequency distribution, such that training can improve the reliability for determining the probability value.

According to an embodiment, the method further includes deconvolving the frequency distribution with one or several convolution kernels prior to selecting the selected class, for example prior to dividing the frequency distribution into the regions, wherein the convolution kernel, for example, describes an influence of a measurement apparatus providing the multitude of measurement values on the frequency distribution.

By deconvolution with the convolution kernel, an influence of measurement devices on the measurement value or the frequency distribution can be reduced or compensated, such that systematic errors can be reduced.

According to an embodiment, the multitude of measurement values represents a series of measurement values and the method includes collecting a multitude of successive measurement values of the series of measurement values to obtain frequency distribution of the series of frequency distributions. For example, dividing the frequency distribution into the regions can take place such that the regions for the frequency distributions of the series of frequency distributions are identical, which is particularly advantageous for determining the probability values by means of MML as the input data for the MML are therefore equidistant.

According to an embodiment, the method includes outputting a light pulse by means of a light source, determining a time period between outputting a light pulse and detecting a photon by means of a detector and providing the time period as measurement value of the multitude of measurement values. For example, determining the time period can take place by means of a correlator based on a first signal output by the light source in the context of outputting the light pulse and a second signal output by the detector as a result of detecting the photon. By the type of determining the measurement information, the light source may have a low intensity, such that the light pulse, for example, represents no danger to the eye. Since the measurement information can also be reliably determined even when the signal/noise ratio of the plurality of measurement values is small, additionally, a particularly sensitive detector, such as an SPAD, can be used, whereby again a low intensity of the light source is sufficient to cause a sufficiently high rate of the useful signal at the detector.

According to an embodiment, the method includes obtaining a plurality of measurement values series in parallel and determining a contribution to the measurement information, each based on the respective frequency distributions of a respective plurality of measurement values of the plurality of measurement values series, wherein the method includes determining, from the selected classes of the respective frequency distribution, the selected class having the highest probability value as a useful signal class and providing a position in the measurement value range represented by the useful signal class as part of the respective contribution to the measurement information. For example, one of the measurement value series each is provided by a respective detector or a pixel of a detector array, such that image information may be obtained based on respective contributions to the measurement information. In examples, the respective contributions to the measurement information further include an adaptation coefficient and/or the probability value of the respective useful signal class. For example, spatial information can be obtained based on the measurement information. By combining the positions with probability values, an accuracy of the spatial information can be increased, for example, a distinction can be made between depth information and information on a surface condition (e.g., reflectivity) of an object. By combining the positions with the adaptation coefficients, for example, movement information can be obtained.

A further embodiment provides an apparatus for determining measurement information based on a multitude of measurement values from a measurement value range. The apparatus is configured to obtain a frequency distribution of a plurality of measurement values, wherein the measurement values of the frequency distribution are each allocated to a class of a plurality of classes of the frequency distribution and wherein a frequency value of a class describes a number of measurement values allocated to the class. Further, the apparatus is configured to divide the frequency distribution into several regions, wherein one of the regions each represents an interval of the measurement value range and includes one or several classes of the frequency distribution. The apparatus is configured to select one of the classes each of a respective region as a selected class of the respective region based on a selection rule, wherein one region feature each is allocated to the regions based on the selection rule. The apparatus is further configured to determine a probability value for one of the selected classes based on the region features, wherein the probability value represents an estimation for the probability with which the selected class represents a value of a useful signal, wherein determining the probability model is based on a statistical model.

Further embodiments provide a LiDAR device comprising the apparatus for determining measurement information. Further, the LiDAR device comprises a light source configured to emit a light pulse and to provide a first signal in connection with emitting the light pulse (e.g., a temporal relationship, e.g., simultaneously or subsequently), a detector configured to detect a photon and to provide a second signal as a result of detecting a photon and a correlator configured to determine, based on the first signal and the second signal, a time period between emitting the light pulse and detecting the photon and to provide the time period as a measurement value of the multitude of measurement values, wherein the measurement value represents a useful signal value when the photon is based on an echo of the light pulse, wherein the useful signal is based on one or several useful signal values and wherein the measurement information includes a position of the selected class of the frequency distribution with the highest probability value. Accordingly, the position of the selected class can represent, with the determined probability, a time period for the echo or a distance of the LiDAR device to an object on which the echo is based.

According to an embodiment, the region feature of the region of a selected class is selectively adapted by considering a previous selected class, if the previous selected class is within a correlation interval, wherein the previous selected class is one of the selected classes of the previous frequency distribution and wherein a position of the correlation interval in the measurement value range and/or a width of the correlation interval is based on an expected change of the value of the useful signal and wherein the expected change is based on a velocity and/or acceleration of the LiDAR device. The LiDAR device is arranged, for example, on a movable apparatus, e.g., a vehicle, whose velocity or acceleration is provided to the LiDAR device as an input signal. Alternatively, the LiDAR device can be able to determine or estimate the velocity and/or acceleration based on the series of frequency distributions. By considering the velocity and/or acceleration, the probability with which a selected class represents a distance of an object can be judged in a particularly accurate manner, as the previous frequency distribution can serve as estimation where the object has been located at an earlier time. Thus, a region feature can be adapted such that this previous knowledge is incorporated in the determination of the probability value.

According to an embodiment, the LiDAR device comprises a plurality of detector units (e.g., a detector array), wherein the LiDAR device is configured to obtain a multitude of measurement values by using a respective detector unit, wherein the apparatus for determining the measurement information is configured to determine, based on the respective multitude of measurement values, a contribution to the measurement information allocated to the respective detector unit.

The apparatus and the LiDAR device are based on the same considerations as the method discussed above. Further, it should be noted that the apparatus could be supplemented with all features, functionalities and details described herein with respect to the inventive method for determining measurement information. The apparatus can be supplemented with the stated features, functionalities and details both individually as well as in combination.

A further embodiment provides a computer program having a program code for performing one of the methods discussed above when the program runs on a computer.

### BRIEF DESCRIPTION OF THE DRAWINGS

Embodiments of the present invention will be detailed subsequently referring to the appended drawings, in which:

FIG. 1 is a flow diagram of a method for determining measurement information according to an embodiment;

FIG. 2 is a schematic diagram of an example of a frequency distribution,

FIG. 3A is a diagram of a further example of a frequency distribution,

FIG. 3B is a diagram with an example of a frequency distribution after applying a convolution kernel,

FIG. 3C is a diagram with an example for selected classes and region features of a frequency distribution,

FIG. 3D is a diagram with an example for probability values of selected classes,

FIG. 4 is a block diagram of a method for an image-correlated learning method according to an embodiment,

FIG. 5 shows diagrams for illustrating a time-correlated analysis according to an embodiment,

FIG. 6 is an illustration of a comparison of a frequency distribution with a previous frequency distribution according to an embodiment,

FIG. 7 is an illustration of an example of a determination of a correlation interval,

FIG. 8 is an illustration of a further example of a determination of a correlation interval,

FIG. 9 is an example of a probability density function of the first arriving photon,

FIG. 10 is an example of spatial depth information and certainty information,

FIG. 11 is an example of a contribution to measurement information based on the adaptation coefficient,

FIG. 12 is a schematic illustration of an apparatus for determining measurement information according to an embodiment,

FIG. 13 is a schematic illustration of a LiDAR device according to an embodiment,

FIG. 14 shows several diagrams with examples of previous selected classes.

### DETAILED DESCRIPTION OF THE INVENTION

In the following, examples of the present disclosure will be described in detail and by using the enclosed descriptions. In the following description, many details will be described to provide a more substantial explanation of examples of the disclosure. However, it is obvious for a person skilled in the art that other examples can be implemented without these specific details. Features of the different described examples can be combined with one another, except that features of a respective combination exclude each other or such a combination is explicitly excluded.

It should be noted that the same or similar elements or elements having the same functionality can be provided with the same or similar references numbers or can be indicated in the same way, wherein a repeated description of elements provided with the same or similar reference numbers or indicated in the same way is typically omitted. Description of elements that have the same or similar references numbers or are indicated in the same way are inter-exchangeable.

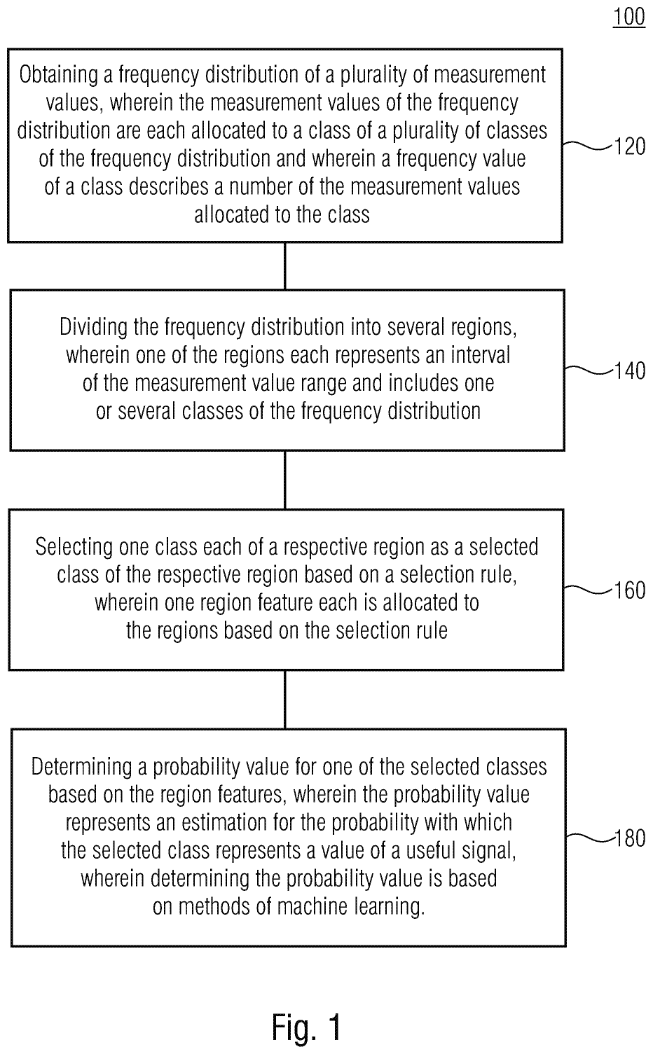

FIG. 1 shows a method 100 for determining measurement information based on a multitude of measurement values of a measurement value range according to an embodiment. The method comprises: Obtaining 120 a frequency distribution of a plurality of measurement values, wherein the measurement values of the frequency distribution are each allocated to a class of a plurality of classes of the frequency distribution and wherein a frequency value of a class describes a number of measurement values allocated to the class; dividing 140 the frequency distribution into several regions, wherein one of the regions each represents an interval of the measurement value range and includes one or several classes of the frequency distribution; selecting 160 one class each of a respective region as a selected class of the respective region based on a selection rule, wherein one region feature each is allocated to the regions based on the selection rule; and determining 180 a probability value for one of the selected classes based on the region features, wherein the probability value represents an estimation for the probability with which the selected class represents a value of a useful signal, wherein determining the probability value is based on methods of machine learning.

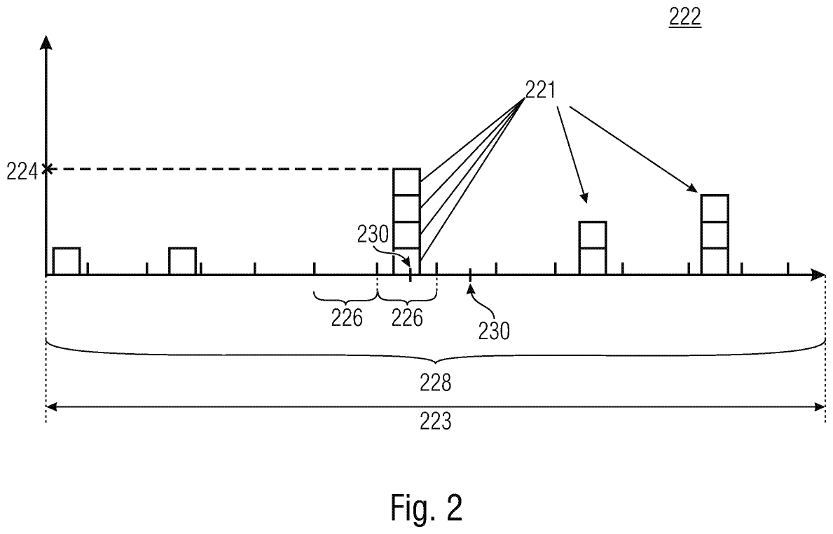

FIG. 2 shows a schematic histogram of an example of a frequency distribution 222 comprising a plurality of measurement values 221. In examples, the frequency distribution 222 is a result of step 120. A value of the respective measurement values 221 is shown by the abscissa. The values of the measurement values are within a measurement value range 223 comprising a plurality 228 of classes, for example class 226, wherein one class represents an interval in the measurement value range 223. The class 226 is located at a position 230 representing a value of the measurement value range 223. A number of measurement values falling into class 226 is represented by a frequency value 224 indicated on the ordinate of the frequency distribution 222.

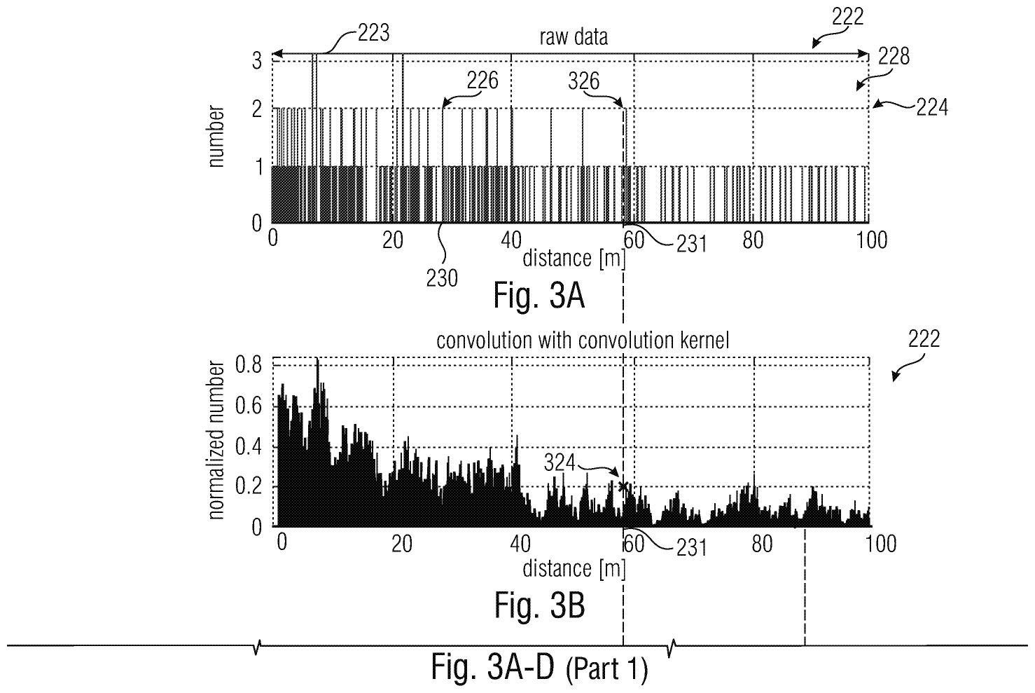

FIG. 3A shows a histogram of a further example of the frequency distribution 222. In this example, the measurement values represent values of a distance illustrated on the abscissa and the ordinate indicating the frequency values of the classes is illustrated as absolute number of measurement values. In this example, the measurement value range is 0 m to 100 m.

According to an embodiment, the method 100 includes an optional step 130 including deconvolving the frequency distribution 222 with one or several convolution kernels. Step 130 can take place, for example, prior to selecting 160 the selected class or, as shown with reference to FIG. 3A to 3D, prior to dividing 140.

For example, the convolution kernel can comprise information on the measurement system or can act similar to an average value filter.

In further examples, by applying a further filter, noise can be removed, for example based on an estimated intensity of a background signal. This noise suppression can take place prior to selecting 160. Thus, wrongly selecting a class as selected class can be prevented, for example, when the selection rule selects the selected class according to the maximum of the frequency values of the region. A reliable selection of the selected classes of the areas can increase the probability that a useful signal class determined from the selected classes approximates the value of the useful signal most accurately. Alternatively, noise suppression can also take place after selecting 160.

FIG. 3B shows a histogram representing an example of a result of the optional application 130 of a convolution kernel to the frequency distribution shown in FIG. 3A. In the shown example, the classes 228 of the frequency distribution 222 remain unamended by applying 130 the convolution kernel, wherein the frequency values of one or several of the classes 222 have been changed. FIG. 3B is an example for a representation of the frequency values as a normalized number.

FIG. 3C shows a diagram 362 illustrating an example of dividing 140 the frequency distribution 222 illustrated in FIG. 3A or FIG. 3B in regions 344 and selecting 160 selected classes 366 for the regions 344. In the shown example, the regions 344 are equidistant and adjacent, however, the regions 344 can also be selected differently depending on other shown features. For example, a class 326 is the selected class of the region 345 of the several regions 344. Dividing 140 can alternatively also be applied directly on the frequency distribution shown in FIG. 3A. The ordinate of the diagram 362 shows a value for region features 364 allocated to the selected classes 366.

In examples, as the example shown in FIG. 3C, selecting 140 the selected classes 366 includes selecting that class 326 of one of the regions 345 as selected class of the region 345 that comprises the highest frequency value 324 and the region feature 364 allocated to the region is based on the frequency value 324 of the selected class 326 of the region 345. For example, the frequency value 324 of the exemplary class 326 (see FIG. 3A, FIG. 3B, FIG. 3C) represents the maximum of the frequency values of all classes of the region 345 and the region feature 367 of the selected class 366 corresponds to the frequency value 324.

FIG. 3D shows a diagram 382, which is an example of determining 180 probability values 384 for the selected classes 366 based on the region features 364 shown in FIG. 3C. Here, the ordinate of the diagram 382 shows the value of the respective probability value. For example, the probability value 384 of the exemplarily selected class 326 of the region 345 represents the probability or certainty with which the position 231 of the selected class 326 corresponds to a distance indicated by a useful signal.

In examples, the method 100 further comprises determining, from the selected classes 366, that one with the highest probability value 384, 387 as a useful signal class 386 to provide a position 388 represented by the useful signal class 386 in the measurement value range 223 as part of the measurement information.

In examples, the method 100 further includes providing the probability value 387 of the useful signal class 386 as part of the measurement information.

In the example shown in FIG. 3D, the probability values 384 have been determined by means of a neural network, however, alternatively, other MML can be used, which could be trained by means of training data and that are suitable, for example, for classifying the region features 364.

In examples, the probability value 384 of the selected class 366 is further determined at the position 230 of the selected class 366. For example, the position 230 can be provided together with the region feature 364 of the selected class 366 for determining the probability value 384.

In examples, the methods of machine learning include an artificial neural network and the method 100 includes training the artificial neural network based on the region features 364 allocated to the regions 344 of the frequency distribution 222.

In examples, the frequency distribution 222 is part of a series of frequency distributions of a respective plurality of measurement values. For example, by means of the method 100, measurement information can be determined for successive frequency distribution.

For example, the multitude of measurement values 221 represents a series of measurement values 221 and the method includes collecting a multitude of successive measurement values 221 of the series of measurement values 221 to obtain a frequency distribution of the series of frequency distributions.

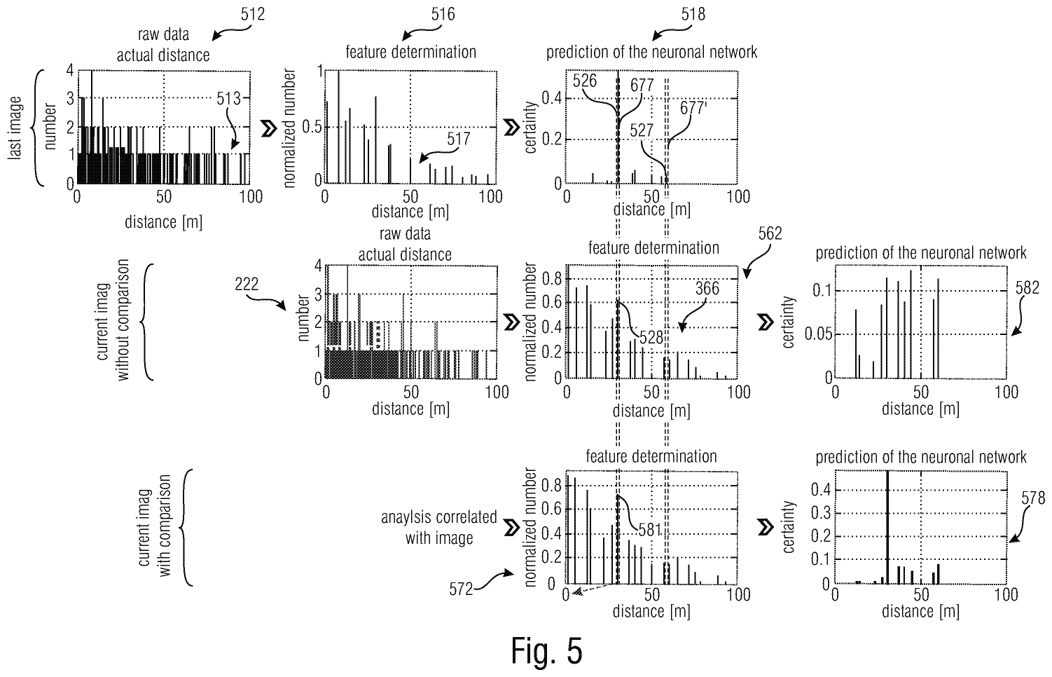

FIG. 6 shows a diagram 662 with a further example of regions 344 with a selected class 366 and allocated region features 364 each, similar to the diagram 362 of FIG. 3C, wherein the underlying frequency distribution is part of a series of frequency distributions. Further, FIG. 6 shows another diagram 672 comprising an example of selected classes 676 and allocated probability values 674 that are determined based on a previous frequency distribution of the series of frequency distributions.

In examples, the method 100 includes comparing the selected classes 366 to the selected classes 676 of a previous frequency distribution of the series of frequency distributions and to adapt or maintain one or several of the region features 364 depending on the comparison and providing the region features 364 for determining the probability value 384, 385, 387. In the following, a selected class 676 of a previous frequency distribution is also referred to as previous selected class 676, wherein a selected class 366 of the frequency distribution 222 can also be referred to as current frequency distribution.

For example, comparing the selected classes 366 to the selected classes 676 of the previous frequency distribution of the series of frequency distributions includes comparing a position 236 of one of the selected classes 366 of the frequency distribution to the positions 230 of one or several of the selected classes 676 of the previous frequency distribution.

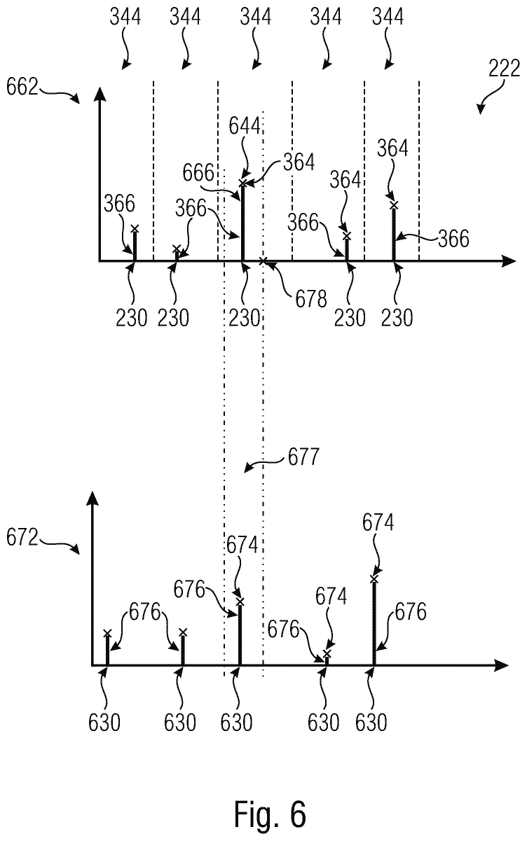

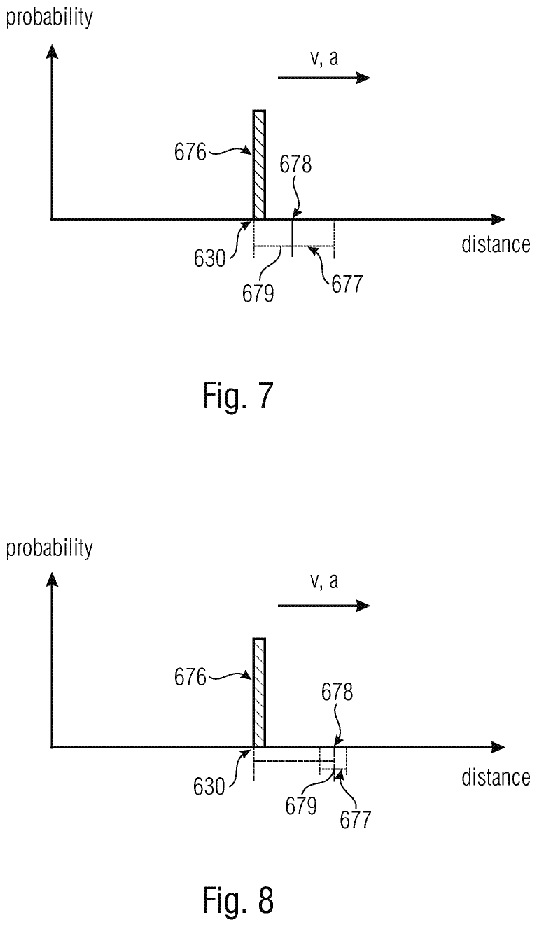

In FIG. 6, an example, of a selected class 666 is shown, which is selected from the selected classes 366 for illustrating purposes. The region feature 664 is allocated to the selected class 666. Further, FIG. 6 shows an example of a correlation interval 677 that can be used for comparing the position 230 of the current selected class 666 to the positions of the previous selected classes 676. The correlation interval may include the position 230 of the selected class 666 as shown in FIG. 6 or may not include the same (cf. FIGS. 7, 8).

In examples, comparing the selected classes 366 to the selected classes 676 of a previous frequency distribution of the series of frequency distributions includes selectively adapting the region feature 664 of the region of a selected class 666 by considering a previous selected class 676, if the previous selected class 676 is within a correlation interval 677, wherein the previous selected class 676 is one of the selected classes of the previous frequency distribution.

In examples, several previous frequency distributions of the series of frequency distributions are considered for the comparison, wherein a selected class of one of the previous frequency distributions is to be considered in the sense of a previous selected class. For example, an influence of a previous selected class can be weighted depending on how far the allocated frequency distribution within the series of frequency distributions dates back compared to the current frequency distribution 222.

Further, it should be noted that the comparison of the positions 230 of the current selected classes 366 to the positions 630 of the previous selected classes 676 can be performed by considering a relative position, i.e., a distance, which is why it can be equivalent to check whether the position 230 of a current selected class 366 is within a correlation interval 677 whose position has been selected with respect to the position 630 of a previous selected frequency distribution or whether the position 630 of a previous selected class 676 is within a correlation interval 677 whose position has been selected with respect to the position 230 of a previous selected frequency distribution.

In examples, comparing the selected classes 366 to the selected classes 676 of a previous frequency distribution of the series of frequency distributions includes determining a comparison position based on positions 630 of the several previous frequency distributions of the series of frequency distributions and selectively adapting the region features 664 of the region of one of the selected classes 666 of the frequency distribution by considering the selected classes used for determining the comparison position, if the comparison position is within a correlation interval 677. For example, a comparison position can be determined for each selected class 366. Alternatively, for example based on the previous selected classes 676, one or several comparison positions can be determined that are compared, for example, to the position 230 of a selected class 666 to selectively determine an adaptation of the region feature 664 of the selected class 666. In other words, the number of the comparison positions can be equal or different to the number of selected classes 366. With respect to comparing the position 230 to the individual positions 630 of the previous selected classes, determining a comparison position offers improved filtering of statistical uncertainties.

For example, for determining the comparison position from the positions 630 of several previous selected classes 676 of different previous frequency distributions, a weighted average value and/or a standard deviation can be determined, wherein the weighting can be based, for example, on the positions 630, the frequency values 224 and/or the probability values 676 of the previous selected classes 676. Further, in examples, the correlation interval is determined based on the positions 630 (e.g., a weighted average and/or a standard deviation), the frequency values 224 and/or the probability values 676 of the previous selected classes 676.

In examples, adapting one of the region features 364 is based on an adaption coefficient, wherein the adaption coefficient is based on the probability value 674 and/or the frequency value 224 and/or a position 630 of one or several selected classes 676 of the previous frequency distribution.

For example, the adaption coefficient is a value that is added to the region feature or subtracted therefrom or a factor by which the region feature is multiplied. When adapting a region feature, the value of the region feature can also be considered.

In examples, adapting the region feature 664 is based on an adaption coefficient, wherein the adaption coefficient and/or the correlation interval 677 is based on the probability value and/or the frequency value and/or a position 630 of the considered previous selected class.

In examples, comparing the selected classes 366 to the selected classes 676 of a previous frequency distribution of the series of frequency distributions includes determining a comparison position based on positions 630 of one or several of the selected classes of several previous frequency distributions of the series of frequency distributions and determining the adaption coefficient based on the probability values and/or the frequency values and/or the positions of the selected classes used for determining the comparison position.

In examples, adapting the region feature 664 is based on an adaptation coefficient, wherein the adaptation coefficient and/or the correlation interval 676 is based on the probability value and/or the frequency value and/or a position of the selected classes used for determining the comparison position.

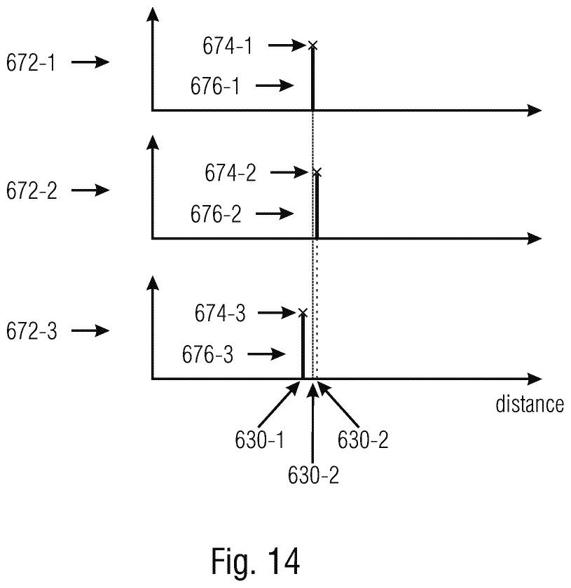

FIG. 14 shows examples of histograms 672-1, 672-2, 672-3 with previous selected classes 676-1, 676-2, 676-3 of several previous frequency distributions of the series of frequency distributions. The previous selected classes 676-1, 676-2, 676-3 comprise the positions 630-1, 630-2, 630-3 and frequency values or probability values 674-1, 674-2, 674-3 allocated to the same and can correspond to the previous selected class 676 with the position 630 and the probability values 674.

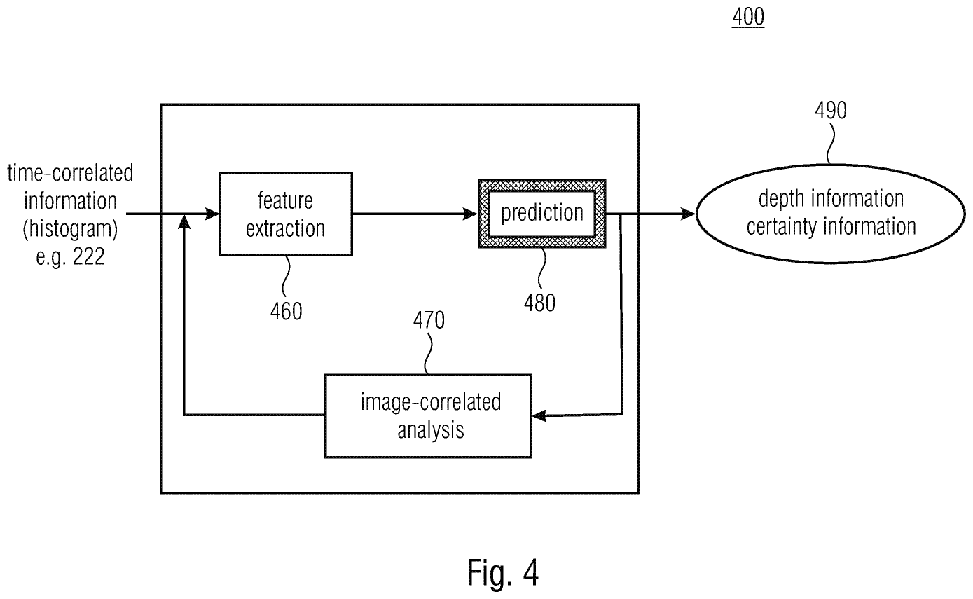

Although the measurement value range represents a distance in FIG. 14, the measurement value range can also represent other quantities, e.g., time. This applies accordingly to FIG. 7, FIG. 8, FIG. 5 and FIGS. 3A-D.

For example, for the adaptation coefficient and/or the correlation interval, an average value and/or a standard deviation of the positions 630 of several previous selected classes 676 is considered. For example, the standard deviation of several positions 630 of previous selected classes 676 can be small if the previous selected classes 676 represent useful signal classes, and can be large if the previous selected classes 676 represent a background signal such that the adaptation coefficient can be adapted accordingly.

In other words, the comparison position, the correlation interval and/or the adaption coefficient can be influenced by information of previous frequency distributions, for example by positions, probability values, frequency values and/or adaptation coefficients of previous selected classes. This means the relationship between comparison positon, adaptation coefficient and correlation interval can be parallel. Comparison position, adaptation coefficient and correlation interval can be based on the information of the multitude of previous frequency distributions.

FIG. 7 and FIG. 8 each illustrate an example for determining the correlation interval 677. In the shown diagrams, the measurement value range 223 is plotted along the abscissa, the ordinate shows, for example, a value of the frequency value 224, 324 or, as illustrated, a probability or another quantity allocated to a selected class.

In examples, as illustrated in FIG. 7, a position 678 of the correlation interval 677 in the measurement value range 223 is based on a position 630 of the selected class 676 in the measurement value range 223, and a width 679 of the correlation interval 677 on an expected change of the value of the useful signal.

In further examples, as illustrated in FIG. 8, a position 678 of the correlation interval 677 in the measurement value range 223 is based on a position 630 of the selected class 676 in the measurement value range 223 and on an expected change of the value of the useful signal, and a width 679 of the correlation interval 677 is based on the expected change of the value of the useful signal.

Considering an expected change of the useful signal can also be combined with considering several previous frequency distributions and can further be combined with determining the correlation interval based on the positions 630, the frequency values 224, the adaptation coefficients and/or the probability values 676 of the previous selected classes 676.

In examples, the method 100 further includes determining the correlation interval and/or the adaptation coefficient by using an artificial neural network.

According to an embodiment, the method 100 further includes outputting a light pulse by means of a light source, determining a time period between outputting a light pulse and detecting a photon by means of a detector and providing the time period as a measurement value 221 of the multitude of measurement values.

In examples, a measurement value 221 of the multitude of measurement values 221 represents a time period between emitting a light pulse and detecting a photon, wherein the measurement value 221 either represents a useful signal value when the photon is based on the light pulse or represents a background signal value and wherein the useful signal is based on one or several useful signal values.

For example, in a TCSPC image, a plurality of measurement values of the time period can be determined to obtain the frequency distribution 222, wherein one or several classes 226 of the frequency distribution 222 can include useful signal values.

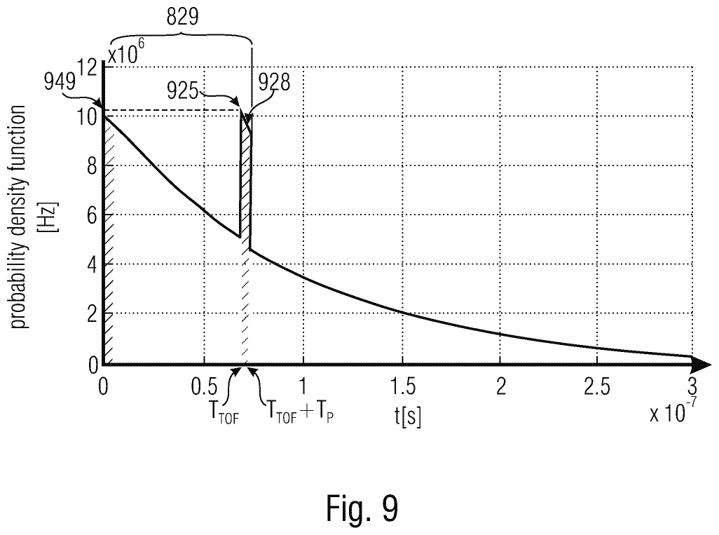

FIG. 9 shows an example of a probability density function of the first incoming photon, for example the first photon after emitting the light pulse. After the arrival of the first photon, measurement of the time period can be terminated and determining a further time period can be started by emitting a further light pulse. The probability with which a photon arrives after emitting a light pulse at a specific time can result from the rates of the background signal and the light pulse and further according to a time of flight (TOF) of the light pulse, which can again be determined from a distance of an object where the light pulse is reflected. FIG. 9 shows exemplarily the probability density function for the arrival of a photon. In the diagram, a region 929 is shown. The classes 928 represent a useful signal, wherein the class 925 comprises the highest probability 949 of all classes of the region 929.

In examples, dividing 140 the frequency distribution into the several regions 344 includes selecting a width of one of the regions 929 such that that class of the region into which a measurement value falling into the region 929 falls with the highest probability represents a class of the useful signal if the useful signal falls into the region.

The probability density function for the first incoming photon for constant ambient light follows the function F1:

F1=r_{B}e^{-r}^{_{B}}^{t},

wherein r_{B} is the background photon rate. By considering the emitted laser pulse, the overall function F is:

$$F = \{ \begin{matrix}{r}_{B} {e}^{- {r}_{B} t} & for 0 \leq t < {T}_{TOF} \\ {r}_{LB} {e}^{- {r}_{LB} ( t - {T}_{TOF} )} {e}^{- {r}_{B} {T}_{TOF}} & for {T}_{TOF} \leq t < {T}_{TOF} + {T}_{p} \\ {r}_{B} {e}^{- {r}_{B} t} {e}^{- {r}_{L} {T}_{P}} & for {T}_{TOF} + {T}_{P} \leq t\end{matrix}$$

Here, r_{B}, r_{L} and r_{LB} represent background emitted laser or total photon rate on the receiver side. T_{TOF} is the arrival time of the first photon from the emitted light. Tₚ is the width of the emitted light pulse. To fulfil the principle that the selected local maxima (e.g., the selected classes 366 of a region 344) have a high or the highest probability of including the target information, the probability of the target class group should be the maximum. If the most unfavorable case is considered, i.e., the laser pulse returns at the very end of the region, and at high or maximum background photon rate as shown in FIG. 9, it follows that:

$$\frac{1 - {e}^{- {r}_{B} {T}_{p}}}{{e}^{- {r}_{B} {T}_{TOF}} ( 1 - {e}^{- {r}_{LB} {T}_{p}} )} < 1$$

Assuming the maximum background photon rate and the received laser photon rate are both 10 MHz, then the width of the outer left region can be derived as:

T_{TOF}+Tₚ<6.69*10⁻⁸s+5*10⁻⁹s=7.19*10⁻⁸s

This means:

Width_{Region}<10.78 m

This is a simplified calculation. In practice, more factors such as the distance attenuation (e.g., an attenuation of the power of the light pulse reflected back with increasing TOF) or the number of measurement values of the frequency distribution should be considered.

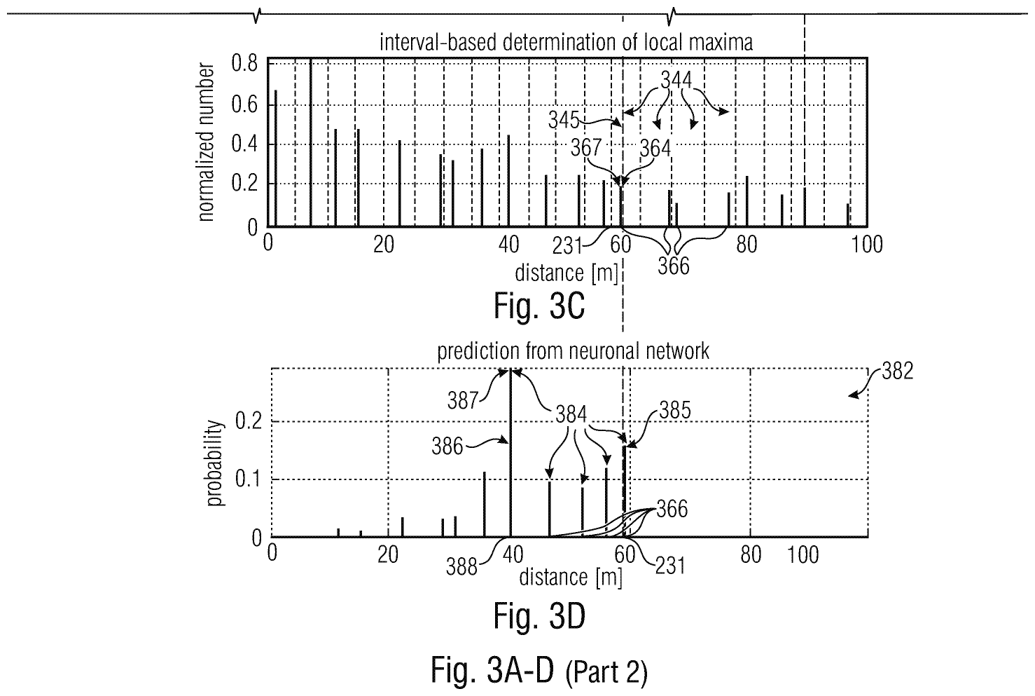

FIG. 4 shows a method model of a method 400 for an image-correlated learning method for TCSPC histograms on pixel level according to an embodiment. The method 400 can correspond to the method 100 of FIG. 1. The method 400 includes feature extraction 460 which can, for example, correspond to steps 140 and 160 of FIG. 1, training and time-correlated analysis 470. The method 400 includes obtaining time-correlated information, e.g., in the form of a histogram, which can correspond, for example, to the frequency distribution 222 of FIG. 2, FIG. 3. The method includes a prediction 480 that can, for example, correspond to step 180. The output information 490 includes depth information and optionally certainty information that can correspond, for example, to the position and the probability value of the usual information. In the following, steps of method 400 will be explained using a detailed example of time-correlated single photon counting (TCSPC), however, this is not the only option of implementing the method 400:
Data sampling: forming raw TCSPC histograms. Histograms having different distances under different ambient light intensities are collected and are used as training data, for example for training the MML or the ANN.
Feature extraction 460 according to the process as shown in FIGS. 3A-D. A filter, e.g., a convolution kernel is applied to the raw data of the histogram, e.g., the frequency distribution 222, to form a new histogram, e.g., as shown in FIG. 3B, which aims to highlight the groups of classes that are similar to the target shape, that are similar, e.g., to a shape of an output light pulse. In the shown example, a one-dimensional convolution kernel is used as a filter. A template is determined according to the ideal pulse shape and pulse width. When the pulse width of the laser is narrow enough, the layer can be given up. Next, the new histogram is divided into several regions 344. Specific local features (e.g., region features 364), e.g., local maxima, are each selected from the regions 344. The width of a region is, for example, defined by two principles (a specific example is described in the context of FIG. 9): 1) the selected local maxima have a high or the highest probability of including the target information (e.g., the useful signal), 2) the overall number of the local maxima (e.g., the overall number of regions 344 into which the frequency distribution 222 is divided) is as small as possible. The selected local maxima and the correlated positions represent the entire histogram. After feature extraction, other information of the histogram can be released from the memory.
Prediction 480: A classifier, e.g., of a forward-coupled neuronal network, is trained by monitored learning based on the local maxima (e.g., the region features 364). The outputs of the classifier represent the certainties (which can correspond, e.g., the probability values 384) of the correlated local maxima. After the training, weightings can be frozen or can be subject to fine-tuning. The final prediction can include depth information and their certainties.
Image-correlated analysis 470: The preceding certainty information (e.g., probability values 384) are used as feedback to support the analysis of the current image. As the target cannot suddenly disappear, more attention should be paid to the coincidence position of potential peaks in different images. One option for realizing the analysis is calculating the information gain (which can correspond, e.g., to the adaptation coefficient). It has to be considered that situations causing a sudden disappearance of the preceding object (when the object moves, e.g., out of the field of view or the close object blocks the distant object) only has minor negative effects as the analysis is based on the histogram of the current image.

In examples, the information gain includes two aspects: gain coefficient and gain width. The gain coefficient is proportional to the certainty of the local feature and is inversely proportional to the standard deviation of class positions (e.g., positions of selected classes) of different images in one region when several images (e.g., several previous frequency distribution) are involved. The gain width is, for example, proportional to the dynamic degree of the scenario (e.g., the radial velocity of the camera, the variance rate of the detected distance history). The information gain can be used internally in the method 100, 400.

FIG. 5 illustrates an example of a time-correlated analysis that can correspond, for example, to the image-correlated analysis 470 or the comparison of the selected class 366 to the selected classes of a previous frequency distribution of the series of frequency distributions, or an example of an implementation of the information gain. The middle row of diagrams in FIG. 5 shows a histogram 222 with raw data (e.g., measurement values), a diagram 562 with region features and a diagram 582 with probability values that can correspond, for example, to the diagrams 222, 362, 382 shown in FIG. 3A, FIG. 3C and FIG. 3D and that can be determined according to the description of FIG. 3A to 3D. The histogram 222 represents a current image, e.g., a current plurality of measurement values 221 or a current TCSPC histogram based whereon measurement information, e.g., depth information, is to be determined. The first row of diagrams in FIG. 5 shows a histogram 512 with raw data similar to the histogram 222. The raw data of the histogram 512 (e.g., the plurality of measurement values) are part of a preceding or last image, e.g., a previous plurality of measurement data that have been analyzed, for example at an earlier time, by the method 100, 400. For example, the histogram 512 includes a previous frequency distribution 513. The diagram 516 shows the selected classes 517 with the allocated region features of the previous frequency distribution 513. The bottom row of diagrams shows a time-correlated analysis of the region features of diagram 562. In the diagram 518 with probability values of the selected classes 517 of the previous frequency distribution 513, one correlation interval 677, 677′ is shown exemplarily for two selected classes 526, 527. In the diagram 562 with the selected classes 366 of the frequency distribution 222, a selected class 528 is within the correlation interval 677, while none of the selected classes 366 of the frequency distribution 222 is within the correlation interval 677′. Thus, an amplification amplitude 588 determined for the selected class 528 that can, for example, correspond to the adaptation coefficient, is greater than zero, such that an amplitude, e.g., the region feature of the selected class 528, is increased.

As described in relation to the prediction 480, the method 100, 400 has the potential, by learning about the relationship between several potential target peaks, to operate in a broader range of an ambient light intensity than the digital processing. Additionally, due to the above mentioned image-correlated analysis, the measurement reliability is higher than in the analysis of a single image and needs only a small amount of additional memory space for saving preceding local maxima and indices that can correspond to the region features 364 and the positions 230 of the selected classes 366. By considering different desired LiDAR applications, this can result in a smaller amount of needed measurements per image, a broader measurement range, a lower sensitivity against ambient light or less requirements for the light emitter. The depth resolution is maintained in the output, e.g., as the positions 230 of the selected classes are stored and hence the position 230 of a selected class identified as a useful signal can be used as depth information. The final outputs can include several types of information, for example the depth map and the certainty map. The spatial analysis can benefit from these maps. Additionally, as the current technologies like coincidence detection and time gating also generate similar histograms, the combination of the method and these technologies can increase the robustness of the system further.

Instead of a forward-coupled network, another algorithm can be used, which is based, however, on the same operating principle as the method.

Other technologies than the filter can be used for supporting future extraction or without the filter when the raw data quality is sufficient for preprocessing, e.g., for selecting the selected classes.

Other algorithms can be implemented for image-correlated analysis, or another algorithm can be used for machine learning, which includes both training as well as image-correlated analysis.

In examples, the method 100, 400 processes the local maxima from a TCSPC histogram, analyses the coincidence information on different frames of TCSPC histograms or offers a certainty or probability of the measurement by using algorithms on TCSPC histograms.

In examples, the method 100 is applied to a LiDAR system or for applications that benefit from prediction, certainty of prediction and deviation from potential information from different blocks.

In examples, the method 100, 400 includes obtaining a plurality of measurement value series in parallel and determining, based on respective frequency distributions of a respective plurality of measurement values of the plurality of measurement values series, a contribution to the measurement information each, wherein the method includes determining, from the selected classes of the respective frequency distributions, the selected class with the highest probability value as a useful signal class and providing a position represented by the useful signal class in the measurement value range as part of the respective contribution to the measurement information. In other words, the method 100, 400 can be applied in parallel to several pluralities of measurement values that are generated, for example, based on signals of a plurality of detectors, e.g., several pixels of a detector array. Thereby, image information can be obtained, for example in the case that the useful signal represents a run time or depth information, spatial depth information can be obtained.

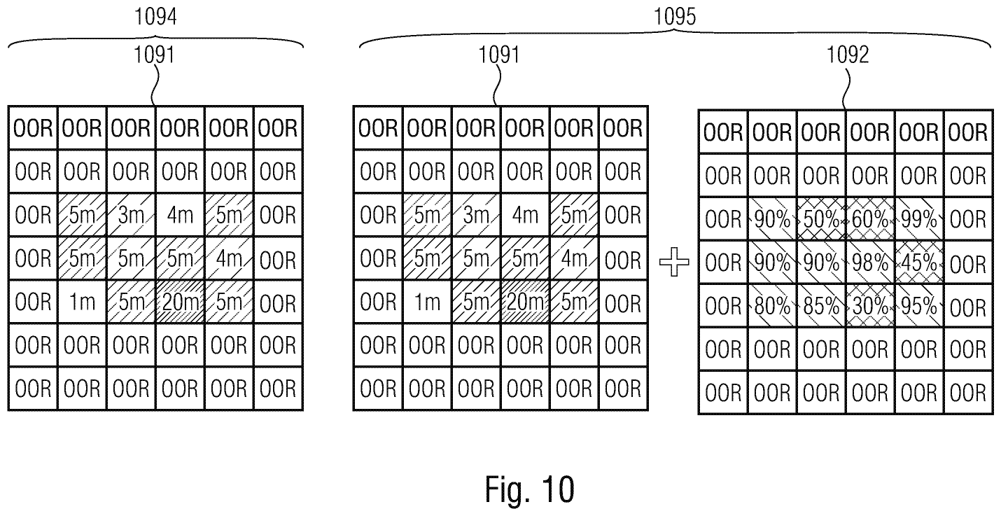

FIG. 10 shows an example of measurement information 1094 including spatial depth information 1091 with a plurality of contributions. The depth information is based, for example, on the positions of useful signal classes that are determined by the method 100, 400 based on one frequency distribution 222 each. Further, FIG. 10 shows an example of measurement information 1095 including the spatial depth information and additionally certainty information 1092, for example the respective probability values of the useful signal classes underlying the depth information 1091. For example, the measurement information 1094 can be interpreted such that an object underlying the removal values comprises a rough surface. As the measurement information 1095 additionally comprises the certainty information 1092, the measurement information 1095 suggests the interpretation that the object comprises a planar surface with different surface reflectivity.

In examples, the method 100 includes providing the adaptation coefficient as part of the measurement information. Here, for example a certainty can be judged whether a class selected as useful signal class represents a true value of the useful signal.

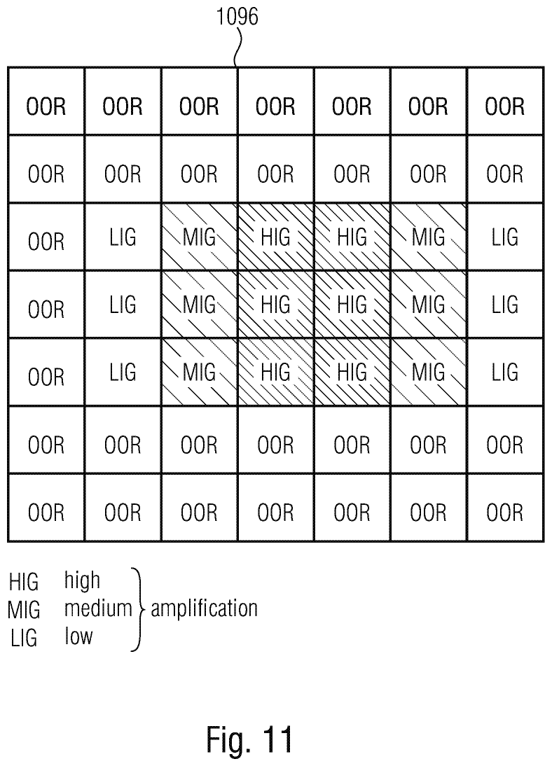

FIG. 11 shows an example of an application of the adaptation coefficient as contribution 1096 to the measurement information. The contribution 1096 includes information based on the adaptation coefficient of the useful signal classes underlying the depth information 1091.

For example, the contribution 1091 allows conclusions on a movement of an object detected based on the depth information 1091.

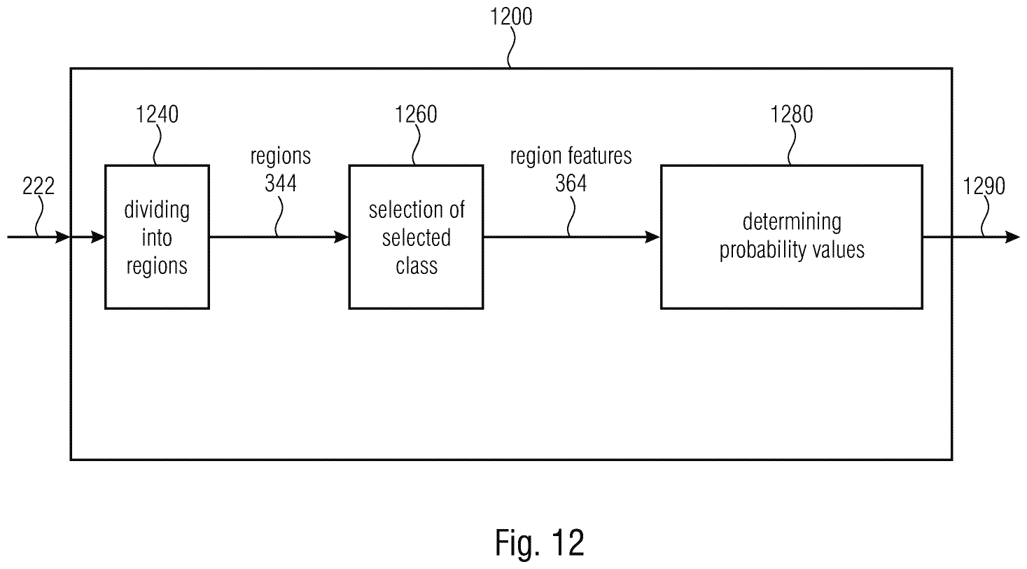

FIG. 12 shows an apparatus 1200 for determining measurement information 1290 based on a multitude of measurement values 221 from a measurement value range 223 according to an embodiment. The apparatus 1200 is configured to obtain a frequency distribution 222 of a plurality of measurement values 221, wherein the measurement values 221 of the frequency distribution 222 are each allocated to a class of a plurality 228 of classes of the frequency distribution 222, and wherein a frequency value 224 of a class 226 describes a number of measurement values allocated to the class 226; and to divide the frequency distribution 222 into several regions 344, wherein one of the regions 344 each represents an interval of the measurement value range 223 and includes one or several classes 226; 326 of the frequency distribution; to select a respective class of a respective region 344 as a selected class 366 of the respective range 344 based on a selection rule, wherein one region feature 364 is allocated to the regions 344 based on the selection rule; and to determine a probability value 384; 387 for one of the selected classes 366 based on the region features 364, wherein the probability value 384; 387 represents an estimation for the probability with which the selected class represents a value of useful signal, wherein determining the probability value is based on a statistical model.

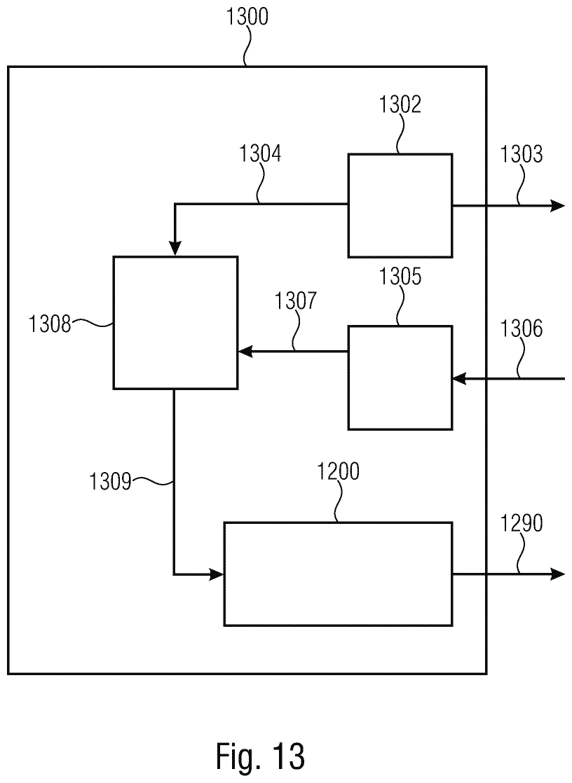

FIG. 13 shows a LiDAR device 1300 according to an embodiment. The LiDAR device 1300 comprises the apparatus 1200, for example as signal processing unit and further includes: a light source 1302 configured to emit a light pulse 1303 and to provide, in connection with emitting the light pulse 1303, a first signal 1304, e.g., an electric signal; a detector 1305 configured to detect a photon 1306 and to provide, as consequence of a detection of a photon, a second signal 1307, e.g., an electric signal; a correlator 1308, e.g., TCSPC electronics, configured to determine, based on the first signal 1304 and the second signal 1307, a time period 1309 between emitting the light pulse and the detection of the photon and to provide the time period 1309 as a measurement value of the multitude of measurement values, wherein the measurement value represents a useful signal value when the photon 1306 is based on an echo of the light pulse 1303, wherein the useful signal is based on one or several useful signal values. Further, the measurement information 1290 can include a position 230 of the selected class 344 of the frequency distribution 222 with the highest probability value.

In examples, the region feature 364 of the region 344 of a selected class 366 is selectively adapted by considering a previous selected class, if the previous selected class is within a correlation interval, wherein the previous selected class is one of the selected classes of the previous frequency distribution and wherein a positon of the correlation interval in the measurement value range and/or a width of the correlation interval is based on an expected change of the value of the useful signal and wherein the expected change is based on a velocity and/or acceleration of the LiDAR device 1300.

In examples, the LiDAR device 1300 comprises a plurality of detector units, wherein the LiDAR device 1300 is configured to obtain a multitude of measurement values each by using a respective detector unit, wherein the apparatus 1200 for determining the measurement information is configured to determine, based on the respective multitude of measurement values, a contribution to the measurement information 1290 allocated to the respective detector unit.

Although some aspects have been described in the context of an apparatus, it is obvious that these aspects also represent a description of the corresponding method, such that a block or device of an apparatus also corresponds to a respective method step or a feature of a method step. Analogously, aspects described in the context of a method step also represent a description of a corresponding block or detail or feature of a corresponding apparatus.

Some or all of the method steps may be performed by a hardware apparatus (or using a hardware apparatus), such as a microprocessor, a programmable computer or an electronic circuit. In some embodiments, some or several of the most important method steps may be performed by such an apparatus.

Depending on certain implementation requirements, embodiments of the invention can be implemented in hardware or in software. The implementation can be performed using a digital storage medium, for example a floppy disk, a DVD, a Blu-Ray disc, a CD, an ROM, a PROM, an EPROM, an EEPROM or a FLASH memory, a hard drive or another magnetic or optical memory having electronically readable control signals stored thereon, which cooperate or are capable of cooperating with a programmable computer system such that the respective method is performed. Therefore, the digital storage medium may be computer readable.

Some embodiments according to the invention include a data carrier comprising electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer.

The program code may be stored, for example, on a machine-readable carrier.

Other embodiments comprise the computer program for performing one of the methods described herein, wherein the computer program is stored on a machine-readable carrier. In other words, an embodiment of the inventive method is, therefore, a computer program comprising a program code for performing one of the methods described herein, when the computer program runs on a computer.

A further embodiment of the inventive method is, therefore, a data carrier (or a digital storage medium or a computer-readable medium) comprising, recorded thereon, the computer program for performing one of the methods described herein. The data carrier, the digital storage medium, or the computer-readable medium are typically tangible or non-volatile.

A further embodiment of the inventive method is, therefore, a data stream or a sequence of signals representing the computer program for performing one of the methods described herein. The data stream or the sequence of signals may, for example, be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment in accordance with the disclosure includes an apparatus or a system configured to transmit a computer program for performing at least one of the methods described herein to a receiver. The transmission may be electronic or optical, for example. The receiver may be a computer, a mobile device, a memory device or a similar device, for example. The apparatus or the system may include a file server for transmitting the computer program to the receiver, for example.

In some embodiments, a programmable logic device (for example a field programmable gate array, FPGA) may be used to perform some or all of the functionalities of the methods described herein. In some embodiments, a field programmable gate array may cooperate with a microprocessor in order to perform one of the methods described herein. Generally, the methods are performed by any hardware apparatus. This can be a universally applicable hardware, such as a computer processor (CPU) or hardware specific for the method, such as ASIC.

In the preceding detailed description, different features have partly been grouped together in examples to rationalize the disclosure. This type of disclosure is not to be interpreted as the intention that the claimed examples comprise more features than explicitly stated in each claim. Rather, as the following claims reflect, the subject matter can be also less than all features of a single disclosed example. Consequently, the following claims are incorporated in the detailed description, wherein each claim can be its own separate example. While each claim can be a single separate example, it should be noted that although dependent claims in the claims relate to a specific combination with one or several other claims, other examples also include a combination of dependent claims with the subject matter of each other dependent claim or a combination of each feature with other dependent or independent claims. Such combinations are included except it is stated that a specific combination is not intended. Further, it is intended that a combination of features of the claim is also included with every other independent claim even when this claim is not directly dependent on the independent claim.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method for determining measurement information based on a multitude of measurement values from a measurement value range, the method comprising:
acquiring a frequency distribution of a plurality of measurement values, wherein the measurement values of the frequency distribution are each allocated to one class of a plurality of classes of the frequency distribution, and wherein a frequency value of a class describes a number of measurement values allocated to the class,
dividing the frequency distribution into several regions, wherein one of the regions each represents an interval of the measurement value range and comprises one or several classes of the frequency distribution,
selecting one class each of a respective region as a selected class of the respective region based on a selection rule, wherein one region feature each is allocated to the regions based on the selection rule,
determining a probability value for one of the selected classes based on the region features, wherein the probability value represents an estimation for the probability with which the selected class represents a value of a useful signal, wherein determining the probability value is based on methods of machine learning.

2. The method according to claim 1, wherein the frequency distribution is part of a series of frequency distributions of a respective plurality of measurement values,
wherein the method further comprises comparing the selected classes to the selected classes of a previous frequency distribution of the series of frequency distributions to adapt or maintain one or several of the region features depending on the comparison, and providing the region features for determining the probability value.

3. The method according to claim 2, wherein comparing the selected classes to the selected classes of the previous frequency distribution of the series of frequency distributions comprises comparing a position of one of the selected classes of the frequency distribution to the positions of one or several of the selected of the previous frequency distribution.

4. The method according to claim 2, wherein comparing the selected classes to the selected classes of a previous frequency distribution of the series of frequency distributions comprises selectively adapting the region feature of the region of a selected class by considering a previous selected class, if the previous selected class is within a correlation interval, wherein the previous selected class is one of the selected classes of the previous frequency distribution.

5. The method according to claim 3, wherein comparing the selected classes to the selected classes of a previous frequency distribution of the series of frequency distribution comprises determining a comparison position based on positions of one or several of the selected classes of several previous frequency distributions of the series of frequency distributions and selectively adapting the region feature of the region of one of the selected classes of the frequency distribution by considering the selected classes used for determining the comparison position if the comparison position is within a correlation interval.

6. The method according to claim 2, wherein adapting one of the region features is based on an adaptation coefficient, wherein the adaptation coefficient is based on the probability value and/or the frequency value and/or a position of one or several selected classes of the previous frequency distribution.

7. The method according to claim 4, wherein adapting the region feature is based on an adaptation coefficient, wherein the adaptation coefficient and/or the correlation interval is based on the probability value and/or the frequency value and/or a position of the considered previous selected class.

8. The method according to claim 6, wherein comparing the selected classes to the selected classes of a previous frequency distribution of the series of frequency distribution comprises determining a comparison positon based on positions of one or several of the selected classes of several previous frequency distributions of the series of frequency distributions and determining the adaption coefficient based on the probability values and/or the frequency values and/or the positions of the selected classes used for determining the comparison position.

9. The method according to claim 5, wherein adapting the region feature is based on an adaptation coefficient, wherein the adaption coefficient and/or the correlation interval is based on the probability value and/or the frequency value and/or a position of the selected classes used for determining the comparison position.

10. The method according to claim 6, wherein the method further comprises providing the adaptation coefficient as part of the measurement information.

11. The method according to claim 4, wherein a positon of the correlation interval in the measurement value range is based on a position of the selected class in the measurement value range and wherein a width of the correlation interval is based on an expected change of the value of the useful signal.

12. The method according to claim 4, wherein a position of the correlation interval in the measurement value range is based on a position of the selected class in the measurement value range and on an expected change of the value of the useful signal and wherein a width of the correlation interval is based on the expected change of the value of the useful signal.

13. The method according to claim 4, wherein the method further comprises determining the correlation interval and/or the adaptation coefficient by using an artificial neuronal network.

14. The method according to claim 1, wherein the method further comprises determining, from the selected classes, the one with the highest probability value as a useful signal class and providing a position in the measurement value range represented by the useful signal class as part of the measurement information.

15. The method according to claim 14, wherein the method further comprises providing the probability value of the useful signal class as part of the measurement information.

16. The method according to claim 1, wherein selecting the selected classes comprises selecting that class of one of the regions as selected class of the region that has the highest frequency value and wherein the region feature allocated to the region is based on the frequency value of the selected class of the region.

17. The method according to claim 1, wherein the regions are equidistant and adjacent.

18. The method according to claim 1, wherein a measurement value of the multitude of measurement values represents a time period between emitting a light pulse and detecting a photon, wherein the measurement value either represents a useful signal value when the photon is based on the light pulse or represents a background signal value and wherein the useful signal is based on one or several useful signal values.

19. The method according to claim 18, wherein dividing the frequency distribution into the several regions comprises selecting a width of one of the regions such that that class of the region into which a measurement value falling into that region falls with the highest probability represents a class of the useful signal if the useful signal falls into the region.

20. The method according to claim 1, wherein the methods of machine learning comprise an artificial neuronal network and wherein the method comprises training the artificial neuronal network based on the region features allocated to the regions of the frequency distribution.

21. The method according to claim 1, wherein the method further comprises deconvolving the frequency distribution with one or several convolution kernels prior to selecting the selected class.

22. The method according to claim 1, wherein the multitude of measurement values represents a series of measurement values and wherein the method further comprises collecting a multitude of successive measurement values of the series of measurement values to acquire a frequency distribution of the series of frequency distributions.

23. The method according to claim 1, comprising:
outputting a light pulse by means of a light source,
determining a time period between outputting a light pulse and detecting a photon by means of a detector and
providing the time period as a measurement value of the multitude of measurement values.

24. The method according to claim 1, wherein the method comprises acquiring a plurality of measurement value series in parallel and determining a contribution to the measurement information, each based on the respective frequency distributions of a respective plurality of measurement values of the plurality of measurement values, wherein the method comprises determining, from the selected classes of the respective frequency distribution, the selected class having the highest probability value as a useful signal class and providing a position in the measurement value range represented by the useful signal class as part of the respective contribution to the measurement information.

25. An apparatus for determining measurement information based on a multitude of measurement values of a measurement value range, wherein the apparatus is configured to
acquire a frequency distribution of a plurality of measurement values, wherein the measurement values of the frequency distribution are each allocated to a class of a plurality of classes of the frequency distribution and wherein a frequency value of a class describes a number of measurement values allocated to the class,
divide the frequency distribution into several regions, wherein one of the regions each represents an interval of the measurement value range and comprises one or several classes of the frequency distribution,
select one of the classes each of a respective region as a selected class of the respective region based on a selection rule, wherein one region feature each is allocated to the regions based on a selection rule and
determine a probability value for one of the selected classes based on the region features, wherein the probability value represents an estimation for the probability with which the selected class represents a value of a useful signal, wherein determining the probability value is based on a statistical model.

26. The LiDAR device, comprising the apparatus according to claim 25 and further:
a light source configured to emit a light pulse and to provide a first signal in connection with emitting the light pulse,
a detector configured to detect a photon and to provide a second signal as a result of detecting a photon,
a correlator configured to determine, based on the first signal and the second signal, a time period between emitting the light pulse and detecting the photon and to provide the time period as a measurement value of the multitude of measurement values, wherein the measurement value represents a useful signal value when the photon is based on an echo of the light pulse, wherein the useful signal is based on one or several useful signal values and
wherein the measurement information comprises a position of the selected class of the frequency distribution with the highest probability value.

27. The LiDAR device according to claim 26, wherein the region feature of the region of a selected class is selectively adapted by considering a previous selected class, if the previous selected class is within a correlation interval, wherein the previous selected class is one of the selected classes of the previous frequency distribution and wherein a position of the correlation interval in the measurement value range and/or a width of the correlation interval is based on an expected change of the value of the useful signal and wherein the expected change is based on a velocity and/or acceleration of the LiDAR device.

28. The LiDAR device according to claim 26, wherein the LiDAR device comprises a plurality of detector units, wherein the LiDAR device is configured to acquire a multitude of measurement values by using a respective detector unit,
wherein the apparatus for determining the measurement information is configured to determine, based on the respective multitude of measurement values, a contribution to the measurement information allocated to the respective detector unit.

29. A non-transitory digital storage medium having a computer program stored thereon to perform the method for determining measurement information based on a multitude of measurement values from a measurement value range, the method comprising:
acquiring a frequency distribution of a plurality of measurement values, wherein the measurement values of the frequency distribution are each allocated to one class of a plurality of classes of the frequency distribution, and wherein a frequency value of a class describes a number of measurement values allocated to the class,
dividing the frequency distribution into several regions, wherein one of the regions each represents an interval of the measurement value range and comprises one or several classes of the frequency distribution,
selecting one class each of a respective region as a selected class of the respective region based on a selection rule, wherein one region feature each is allocated to the regions based on the selection rule,
determining a probability value for one of the selected classes based on the region features, wherein the probability value represents an estimation for the probability with which the selected class represents a value of a useful signal, wherein determining the probability value is based on methods of machine learning,
when said computer program is run by a computer.
